(19) United States
(12) Patent Application Publication
(10) Pub. No.: US 2017/0279402 A1
(43) Pub. Date: Sep. 28, 2017

(54) PHOTOVOLTAIC MACRO-MODULE FOR SOLAR POWER GENERATION

(71) Applicant: X Development LLC, Mountain View, CA (US)

(72) Inventors: Philipp H. Schmaelzle, Mountain View, CA (US); Dominico Julian, Oakland, CA (US); Leo F. Casey, San Francisco, CA (US); Thomas P. Hunt, Oakland, CA (US); Todd A. Pelman, Moss Beach, CA (US); Scott W. Aldous, Palo Alto, CA (US); Garrison J. Buchanan, Woodside, CA (US); Raphael J. Feldman, San Francisco, CA (US); William J. Shields, San Francisco, CA (US); Justin S. Hyde, San Francisco, CA (US); Duncan W. Harwood, Santa Clara, CA (US)

(21) Appl. No.: 15/332,619

(22) Filed: Oct. 24, 2016

Related U.S. Application Data
(60) Provisional application No. 62/313,531, filed on Mar. 25, 2016.
(60) Provisional application No. 62/366,411, filed on Jul. 25, 2016.

(51) Int. Cl. H02S 10/40; H01L 31/049; H01L 31/05; B63B 22/18; H02S 40/34; H02S 40/36; H02S 40/32; H01L 31/18; H01L 31/048; H01L 31/02

(52) U.S. Cl. CPC H02S 10/40; H01L 31/0488; H01L 31/049; H01L 31/0504; H01L 31/02021; H02S 40/34; H02S 40/36; H02S 40/32; H01L 31/1876; H01L 31/188; B63B 22/18

(57) ABSTRACT

A photovoltaic (“PV”) macro-module for solar power generation includes a plurality of solar cell strings disposed within a laminated support structure. The solar cell strings generate solar power in response to light incident upon a frontside of the solar cell strings. Each of the solar cell strings includes a plurality of solar cells electrically connected in series. The laminated support includes a substrate layer to provide physical environmental protection to a back side of the solar cell strings, a backside encapsulant layer disposed between the substrate layer and the solar cell strings, and a frontside encapsulant layer. The backside encapsulant layer conforms to and molds around the back side of the solar cell strings while the frontside encapsulant layer conforms to and molds around the frontside of the solar cell strings. The laminated support structure is compliant to rolling or folding.

### REFERENCE TO RELATED APPLICATION

This application claims the benefit of both U.S. Provisional Application No. 62/313,531 filed on Mar. 25, 2016, and U.S. Provisional Application No. 62/366,411 filed on Jul. 25, 2016, the contents of which are both incorporated herein by reference. The present application is related to a U.S. Application entitled “Fabrication Techniques of a Photovoltaic Macro-Module for Solar Power Generation,” Attorney Docket Number 10134P421, filed on the same day as this application.

### TECHNICAL FIELD

This disclosure relates generally to the field of solar power generation, and in particular but not exclusively, relates to floating solar power generation.

### BACKGROUND INFORMATION

As societies continue to industrialize throughout the world, the demand for affordable and plentiful electricity continues to grow. Renewable sources of electricity are increasingly being relied upon to meet this ever growing demand. One popular renewable source of electricity is solar power generation.

The construction of solar power plants is expensive and labor intensive. Each solar power module must be mechanically supported and electrically connected. Additionally, solar power plants may consume acres of otherwise usable land. A solar power module that can be economically fabricated, that is quickly, efficiently, and safely deployable in areas that are otherwise not being used, would be desirable and likely increase the adoption rate of commercial scale solar power generation.

### BRIEF DESCRIPTION OF THE DRAWINGS

Non-limiting and non-exhaustive embodiments of the invention are described with reference to the following figures, wherein like reference numerals refer to like parts throughout the various views unless otherwise specified. Not all instances of an element are necessarily labeled so as not to clutter the drawings where appropriate. The drawings are not necessarily to scale, emphasis instead being placed upon illustrating the principles being described.

FIG. 1 is an illustration of a photovoltaic (“PV”) macro-module, in accordance with an embodiment of the disclosure.

FIG. 2A is a functional block diagram of a junction box including centralized circuitry of a PV macro-module, in accordance with an embodiment of the disclosure.

FIG. 2B illustrates demonstrative distributed circuitry embedded throughout a PV macro-module, in accordance with an embodiment of the disclosure.

FIG. 3 is an illustration of a higher voltage PV macro-module, in accordance with an embodiment of the disclosure.

FIG. 4 is an illustration of a lower voltage PV macro-module, in accordance with an embodiment of the disclosure.

FIG. 5A is a backside illustration of a floating PV macro-module, in accordance with an embodiment of the disclosure.

FIG. 5B is profile illustration of a floating PV macro-module, in accordance with an embodiment of the disclosure.

FIG. 6A is a cross-sectional material stack illustration of a laminated support structure for a PV macro-module, in accordance with an embodiment of the disclosure.

FIG. 6B is a cross-sectional material stack illustration of a laminated support structure for a PV macro-module with integrated buoyancy, in accordance with an embodiment of the disclosure.

FIG. 6C is a cross-sectional material stack illustration of a laminated support structure including a glass panel layer, in accordance with an embodiment of the disclosure.

FIG. 6D is a cross-sectional material stack illustration of a laminated support structure including both front and back glass panel layers, in accordance with an embodiment of the disclosure.

FIG. 7 is an illustration of a foldable PV macro-module including fold zones and solar cell zones, in accordance with an embodiment of the disclosure.

FIG. 8 is a flow chart illustrating a method of roll-to-roll fabrication of a PV macro-module, in accordance with an embodiment of the disclosure.

FIG. 9 illustrates the roll-to-roll fabrication technique, in accordance with an embodiment of the disclosure.

FIG. 10 is a flow chart illustrating a method of batch fabrication of a PV macro-module, in accordance with an embodiment of the disclosure.

FIGS. 11A-11D illustrate different portions of the batch fabrication technique, in accordance with an embodiment of the disclosure.

### DETAILED DESCRIPTION

Embodiments of an apparatus, system and method for fabrication of a photovoltaic (“PV”) macro-module are described herein. In the following description numerous specific details are set forth to provide a thorough understanding of the embodiments. One skilled in the relevant art will recognize, however, that the techniques described herein can be practiced without one or more of the specific details, or with other methods, components, materials, etc. In other instances, well-known structures, materials, or operations are not shown or described in detail to avoid obscuring certain aspects.

Reference throughout this specification to “one embodiment” or “an embodiment” means that a particular feature, structure, or characteristic described in connection with the embodiment is included in at least one embodiment of the present invention. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

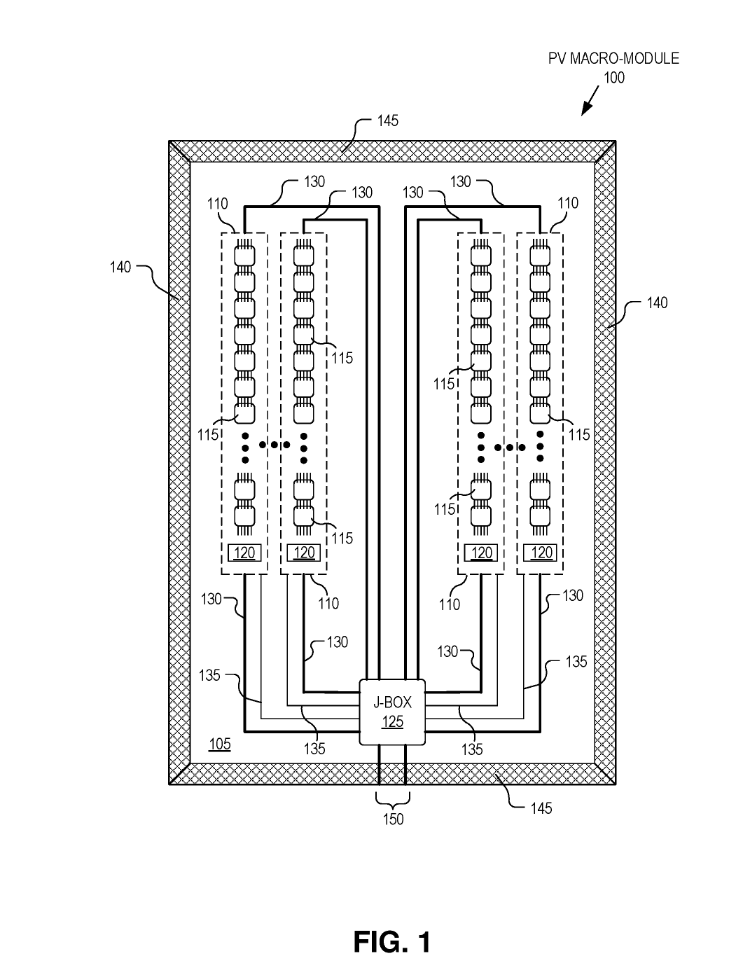

FIG. 1 is an illustration of a photovoltaic (“PV”) macro-module 100, in accordance with an embodiment of the disclosure. The illustrated embodiment of PV macro-module 100 includes laminated support structure 105, solar cell strings 110 including solar cells 115, distributed circuitry 120, a junction box 125, power lines 130, signal lines 135, edge connections 140, end connections 145, output ports 150.

Solar cell strings 110 each includes a plurality of solar cells 115 electrically connected in series to generate solar power and a current in response to light incident upon a frontside of PV macro-module 100. PV macro-module 100 may include any number of solar cell strings 110 each having any number of solar cells 115. However, PV macro-module 100 is well-suited for kilowatt power generation and may be coupled with additional instances of PV macro-module 100 for megawatt power generation. For example, each solar cell 115 may be designed to output 10 A @ 1V, each solar cell string 110 may include between 50 and 1000 series connected solar cells 115 to generate 10 A @ 1000V on output ports 150. Of course, the actual number of solar cell strings 110, number of solar cells 115 per solar cell string 110, amperage and voltage output may be selected by design and vary outside the above demonstrative ranges and/or that illustrated in FIG. 1. PV macro-module 100 is referred to as a “macro” module to indicate that the design of PV macro-module 100 is well-suited for integrating large numbers (e.g., 100's or 1000's) of solar cells 115 into a single contiguous module or form factor for commercial grade power generation. However, it is also anticipated that the designs disclosed herein are also applicable to sub-kilowatt power generation applications.

In the illustrated embodiment, PV macro-module 100 encases solar cell strings 110 within laminated support structure 105. Laminated support structure 105 is fabricated as a multi-layer laminated structure that is durable, environmentally benign/inert, and relatively low cost when compared to conventional commercial grade solar power generating systems that include rigid housings and bulky support structures. Laminated support structure 105 is a mat-like protective encasement that surrounds solar cell strings 110 and is compliant to rolling or folding. By embedding solar cell strings 110 in a laminated structure, expensive frames and mechanical support infrastructures can be avoided thereby facilitating simplified storage and quick deployment in a variety of environmental conditions. For example, PV macro-module 100 may be deployed in horizontal, inclined, or vertical orientations. PV macro-module 100 can be temporarily deployed for short-term power generation (e.g., portable deployments, deployments in the event of unexpected power grid failure, deployments in the event of natural disasters, etc.), seasonal power generation, or long-term/quasi-permanent deployments (e.g., multi-year or multi-decade). PV macro-module 100 can be tailored for deployment over land or water bodies (e.g., water reservoirs). In some embodiments, PV macro-module 100 may be implemented as a series of smaller (e.g., 2 m by 1 m) rigid PV panels (e.g., rigid glass solar panels) physically linked end-to-end. These rigid PV panels may be floated in sections that each includes one or more of the rigid PV panels. Each section may be flexibly linked end-to-end to another section to form a longer column (or row), as represented by PV macro-module 100 in FIG. 1. The periodic flexible connection points between each section provides compliancy to wave action.

In particular, embodiments disclosed here in are specifically designed for floating solar power generation. Floating solar deployments can have a number of advantages. For example, the surfaces of water reservoirs often constitute vast areas not being used for other productive purposes. One side benefit of floating solar is the reduction in water evaporation from reservoirs or other waterbodies over which PV macro-module 100 may be deployed. Furthermore, the inherent attributes of a water deployment can be leveraged for effective cooling that increases operational efficiency, reduces operations and maintenance costs, and extends expected service lifespans.

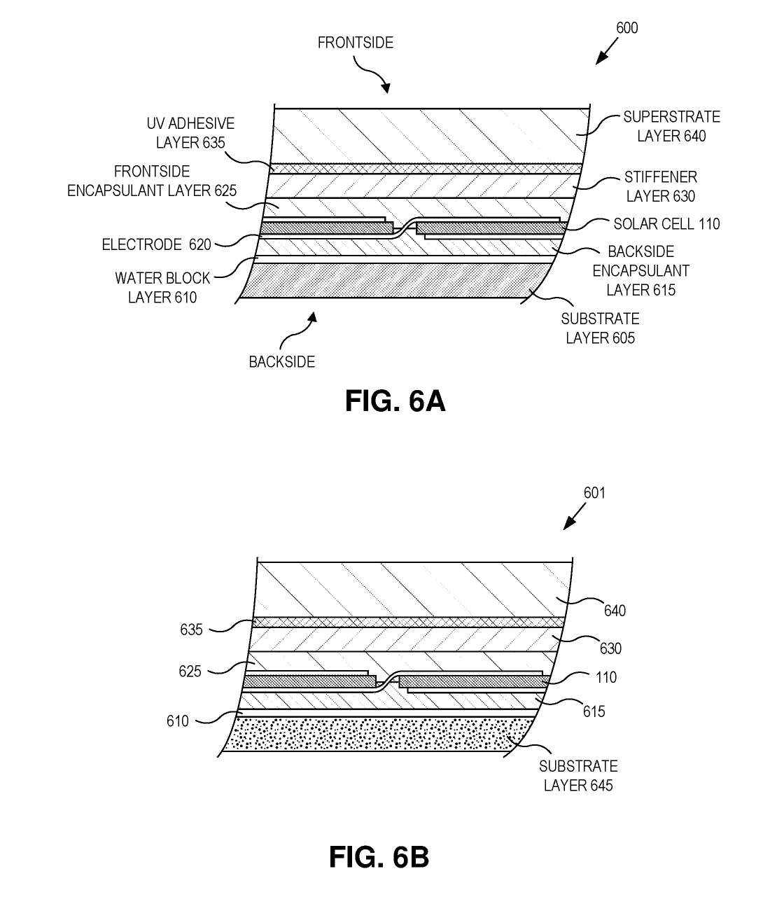

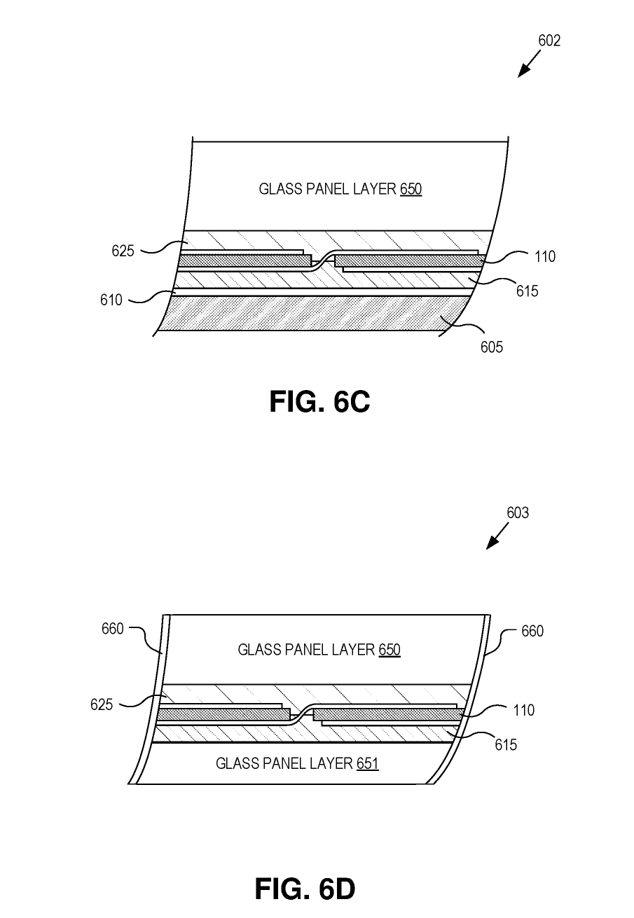

In one embodiment, solar cells 115 are fabricated of monocrystalline silicon; however, in other embodiments, solar cells 115 may be implemented using polycrystalline silicon, thin film technologies, other semiconductor materials (e.g., gallium arsenide), or other solar cell technologies. The illustrated embodiment of each solar cell string 110 includes a plurality of solar cells 115 coupled in series. In other embodiments, solar cell strings 110 may also include a group of parallel coupled solar cells 110 that are coupled in series with other parallel coupled solar cells 110. Furthermore, the physical layout of these series coupled solar cells 115 may assume a variety of different patterns and routes. For example, a given solar cell string 110 may follow a straight path, a zigzag or serpentine path, a curved path, a spiral path, or trace out any number of a geometric patterns (e.g., concentric rectangles, etc.). In one embodiment, solar cells 115 within a solar cell string 110 are interconnected via embedded conductive interconnects that alternate physical connections on the frontside and backside of consecutive cells (e.g., see FIGS. 6A-6D). Furthermore, solar cell strings 110 may be interconnected to each other (series or parallel) via power lines 130 also embedded within laminated support structure 105.

In one embodiment, the layout of solar cell strings 110 is optimized to position solar cells 115 from different solar cell strings 110 that have similar potentials adjacent to each other. This layout optimization enables reduced inter-cell separations since voltage differences between adjacent solar cells 115 (and their interconnections) are reduced. A smaller inter-cell separation, increases solar cell densities. In yet another embodiment, layout of solar cells strings 110 is optimized to position solar cells 115 having lower potential differences from the surrounding environmental (e.g., ground potential of surround waterbody) are positioned towards the perimeter near the edges of PV macro-module 100 while solar cells 115 having higher potential differences from the surrounding environment are positioned towards the interior of PV macro-module 100. For example, in one embodiment, the potential difference of solar cells 115 relative to the surrounding environment increases with distance from an edge of PV macro-module 100.

In the illustrated embodiment, power lines 130 electrically connect solar cell strings 110 to power circuitry within junction box 125. Junction box 125 includes the centralized circuitry for managing operations of solar cell strings 110, collecting the solar power or current generated by solar cell strings 110, and outputting the solar power via output ports. In the illustrated embodiment, junction box 125 is a single enclosure that includes both power electronics, communication electronics, sensors, and control logic for PV macro-module 100. In one embodiment, junction box 125 is a hermetically sealed enclosure that dissipates heat to its surrounding environment. In other embodiments, junction box 125 may represent multiple interconnected physical enclosures. Junction box 125 may be integrated into laminated support structure 105, mounted on a frontside, backside, or both sides of laminated support structure 105. In one embodiment, a cutout or hole is made into laminated support structure 105 into which junction box 125 is disposed. In the illustrated embodiment, junction box 125 is disposed proximate to one end of PV macro-module 100, though it may also be mounted along a side edge or other interior location. In one embodiment, the centralized circuitry within junction box 125 is coupled to one or more solar cells that provide operational power to junction box 125. In one embodiment, these solar cells are separate or otherwise isolated from the other solar cells 115 to provide backup operational power to junction box 125. This backup operational power enables command and control features within junction box 125 to operate even in the absence of shore power and when solar cells 115 are placed in a shutdown state.

In addition to the centralized circuitry incorporated into junction box 125, the illustrated embodiment of PV macro-module 100 also includes distributed circuitry 120 integrated within laminated support structure 105 and disposed throughout PV macro-module 100. Distributed circuitry 120 is coupled to solar cell strings 110 to selectively route current generated by solar cells 115 under the influence and control of a controller within junction box 125. Distributed circuitry 120 may be coupled in various shunting paths across different portions of the various solar cell strings 110 to bypass failing sections of solar cells 110, to discharge and shutdown one or more solar cell strings 110 (or portions thereof), to respond to a failure or short circuit condition sensed within PV macro-module 100, or otherwise. In some embodiments, distributed circuitry 120 includes switches, transistors, or fuses disposed in line with solar cells 115, which can be selectively activated (e.g., energized, blown, etc) to open circuit or short circuit sections of solar cell strings 110. For example, in one embodiment, a default state of PV macro-module 100 may include shorting or clamping sections of solar cell strings 110 to a safe voltage or even a ground state (note, in some embodiments, the ground state may be referenced to the water as opposed to a ground electrode). Signal lines 135 are routed within laminated support structure 105 to interconnect distributed circuitry 120 to junction box 125. Signal lines 135 may be parallel or serial datapaths, and may include one or more addressing lines, command lines, and/or sensing lines. Although FIG. 1 illustrates signal lines 135 as distinct physical lines, in other embodiments, power line communications or even wireless communications may be used in place of signal lines 135.

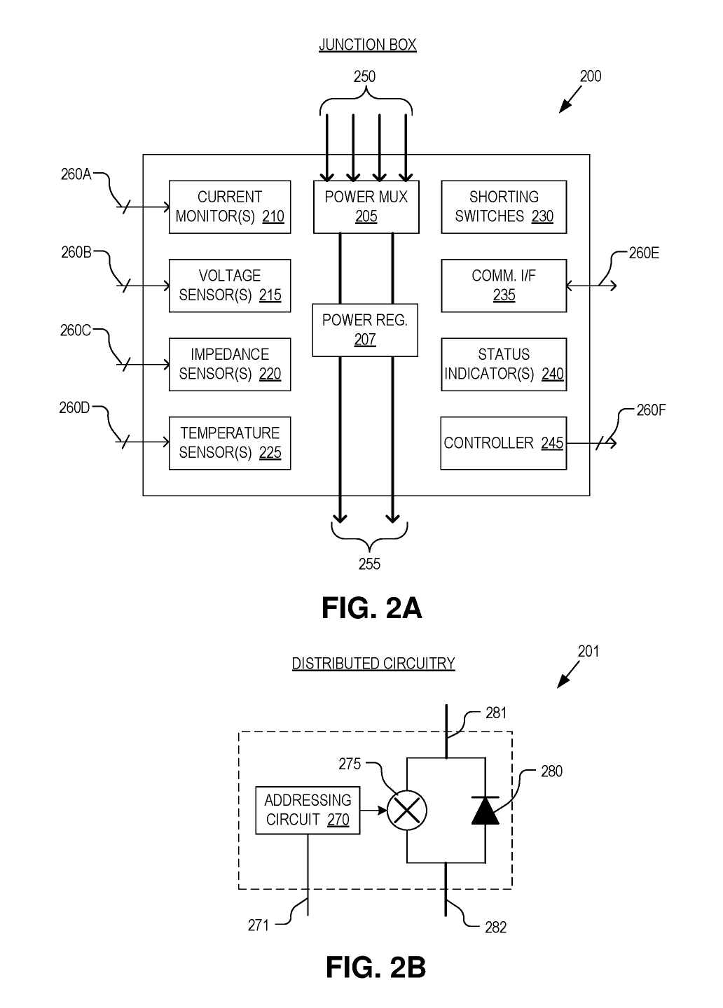

Distributed circuitry 120 also serves to increase yield rates for PV macro-modules 100. As mentioned above, PV macro-module 100 may include 100's or even 1000's of solar cells 115. If every solar cell 115 is required to function in order to obtain a functioning PV macro-module 100, the yield rate of PV macro-modules 100 could be unviable for mass production. Accordingly, distributed circuitry 120 includes inline fuses and switches dispersed throughout solar cell strings 110 to actively shunt or otherwise isolate non-functioning solar cells 115, or sections of solar cells 115, from the remaining functioning solar cells 115. By sensing and actively isolating non-functioning solar cells 115 from functioning solar cells 115, yield rates for PV macro-modules 100 can be substantially increased. In one embodiment, distributed circuitry 120 includes a pair of inline fuses surrounding a group of solar cells 115 on either end and a shunting switch that bridges/shunts the group of solar cells 115 surrounded by the inline fuses. These inline fuses can be selectively blown and the shunting switch affirmatively asserted to isolate the group of solar cells 115 and route current around the isolated group. Of course, the pair of inline fuses and shunting switch structure may be repeated throughout PV macro-module 100 to selective isolate different sections as needed. Embodiments of distributed circuitry 120 may include additional and/or alternative elements (e.g., bypass diodes) as discussed below in connection with FIG. 2B. In one embodiment where solar cell strings 110 are disposed across laminated support structure 105 using a zigzag or serpentine layout or path, bypass diodes and/or shunting switches may be coupled across segments of a given solar cell string 110 between adjacent folded sections of the path to provide a minimum or reduced separation distance between the connection points where the bypass diode and/or shunting switches couple.

PV macro-module 100 may further include edge treatments for physically interconnecting and mounting one or more PV macro-modules 100 in a variety of environments. For example, the illustrated embodiment of PV macro-module 100 includes edges connections 140 disposed along side edges of PV macro-module 100 and end connections 145 disposed along the shorter end edges of PV macro-module 100. Edge connections 140 represent edge treatments that facilitate mechanically connecting PV macro-module 100 to other PV macro-modules 100 when deployed in the field. Example edge connections 140 may include zippers, snaps, hook and loop fasteners, tape, eyeholes for lacing, clips etc. Edge connections 140 may further include various contours (e.g., scallops) or through holes to prevent pooling of rain or water and facilitate water drainage at the edges of a given PV macro-module 100 even if positioned as an interior module of a large interconnected array of PV macro-modules 100. Thus, edge connections 140 facilitate quick deployment of large contiguous solar power systems of variable size and power ratings.

End connections 145 represent end treatments that facilitate mechanical mounting or holding of PV macro-module 100 taut when unfolded or unrolled. For example, end connections 145 may include loops, periodic grommet holes, clips, or other mounting locations for attaching various types of mounting tethers or tensioning systems to PV macro-module 100 in a fully deployed orientation (e.g., unfolded, unrolled) while resisting environmental forces (e.g., wind, waves, etc.). Collectively, edge connections 140 and end connections 145 facilitate variable size deployments, that can be mechanically and electrically interconnected into a contiguous system and which can be mounted in a variety of orientations (vertical, horizontal, inclined) and environments (e.g., land or water). Although FIG. 1 illustrates side connections 140 as residing along the longer edge of PV macro-module 100 and end connections 145 as residing along the shorter edge, these edge treatments may be swapped or even interspersed along a common edge/end.

FIG. 2A is a functional block diagram of a junction box 200 including centralized circuitry of a PV macro-module, in accordance with an embodiment of the disclosure. Junction box 200 represents one possible implementation of junction box 125 illustrated in FIG. 1. The illustrated embodiment, of FIG. 2A includes a power multiplexer 205, a power regulator 207, a current monitor(s) 210, a voltage sensor(s) 215, an impedance sensor(s) 220, a temperature sensor(s) 225, shorting switches 230, a communication interface 235, status indicators 240, a controller 245, power input ports 250, power output ports 255, and various signal/sense lines 260A-F. In one embodiment, the functional units illustrated in FIG. 2A are all integrated into a single enclosure; however, in various other embodiments, junction box 200 may represent multiple physical enclosures or devices that do not necessarily share a common physical box. Rather, these components are referred to as centralized circuitry to indicate that the functions they perform do not necessarily affect just a single solar cell string, but rather, have corporate responsibilities for overall management and function of PV macro-module 100.

Power multiplexer 205 is coupled via power lines 250 to solar cell strings 110 to receive and combine their output solar power and current. In one embodiment, power multiplexer 205 couples solar strings 110 in parallel; however, in other embodiments power multiplexer 205 may couple solar cell strings 110 in a variety of series or parallel combinations. In some embodiments, power multiplexer 205 forms a fixed connection between solar cell strings 205; however, in other embodiments, power multiplexer 205 is capable of making and breaking power connections between the various solar cell strings 110 under the influence of controller 245 to form intelligent connections and reroute current based upon present conditions within PV macro-module 100. Power multiplexer 205 outputs the combined solar power and current on power output ports 255. In one embodiment, junction box 250 outputs a 1000V @ 10 A. Of course, PV macro-module 100 may be designed for other voltage and current ratings based upon the total number of solar cells and how they are ganged.

Power regulator 207 is coupled to receive the solar generated power from solar cell strings 110 and generate a regulated output voltage on output ports 255. In the illustrated embodiment, power multiplexer 205 is coupled between solar cell strings 110 and power regulator 207; however, in other embodiments, each solar cell string 110 may be coupled to a dedicated power regulator within junction box 125 and the output of these dedicated power regulators coupled together by a power multiplexer before being output on output ports 255. In yet other embodiments, power multiplexer 205 and power regulator 207 may be functions that are integrated into a hybrid power block that provides both power multiplexing and power regulation. In one embodiment, power regulator 207 is a DC-to-DC converter, which may incorporate a transformer, to step up or step down the voltage on output ports 255 versus the voltage received on input power lines 250. In other embodiments, power regulator 207 performs maximum power point tracking for the entire PV macro-module 100 or sub-sections thereof. In yet other embodiments, junction box 200 may include a DC-AC converter to convert the DC power received from solar cell strings 110 to AC power for output on output ports 255. In one embodiment, the power output on output ports 255 is a three-phase AC power signal. These and other power regulation functions may be incorporated into power regulator 207.

In one embodiment, controller 245 is coupled to each of the other functional components within junction box 250 to receive real-time feedback readings and orchestrate operations. Controller 245 may be implemented as hardware logic (e.g., application specific integrated circuit, field programmable gate array, etc.), software or firmware instructions executing on a microcontroller, or a combination of both. Communication interface 235 provides a communication link to controller 245 for sending/receiving off-system messages. Communication interface 235 may be implemented as a wired link (e.g., power line communications, Ethernet, etc.) or wireless link (e.g., wifi, cellular, etc.). In one embodiment, controller 245 and communication interface 235 form components of an industrial control system, such as a supervisory control and data acquisition (“SCADA”) system. Status indicators 240 may include multi-color LED status lights, a display screen, or other visual/audible feedback indicators. In some embodiments, controller 245 monitors output ports 255 for a connection to a power delivery system. If a suitable power delivery system is detected, controller 245 places distributed circuitry 120 into an operational state for power generation. If a suitable power delivery system is not detected, then controller 245 places distributed circuitry 120 into a safe mode (e.g., clamp solar cells, discharge internal nodes, etc.).

Current monitor 210, voltage sensor 215, impedance sensor 220, and temperature sensor 225 collectively represent sensor circuitry for supervising the safe operation of PV macro-module 100. These systems provide real-time monitoring and fault detection (e.g., short circuit faults, overheat conditions, environmental intrusions causing solar cell failures, etc.). In one embodiment, each of these systems is coupled to various internal connection points both within laminated support structure 105 via signal lines 260 or to internal connection points within junction box 200.

In one embodiment, current monitor 210 is coupled to power multiplexer 205 to monitor the current on each power line 250. In one embodiment, current monitor 210 is coupled via signal lines 260A to solar cell strings 110 to monitor the current in each solar cell string 110. Current measurements may be thresholded and auto shutdown or current path rerouting executed by controller 245 as needed. Excessive current readings may be indicative of a short circuit fault while low current readings may be indicative of a failed solar cell 115, which needs to be shunted for current rerouting via distributed circuitry 120. In one embodiment, controller 245 includes logic to clamp solar cell strings 110 to a safe voltage in modest lighting situations. For example, during dawn or dusk, or under bright starlight or moonlight, little current is generated, but solar cells strings 110 may generate a significant open circuit voltage. When these scenarios are sensed (e.g., using current monitor 210), controller 245 can clamp the open circuit voltage for worker safety. Clamping may be achieved using distributed circuitry 120 and/or shorting switches 230. Clamping solar cell strings 110 to a safe voltage may include shorting ends or sub-sections of the solar cell strings 110.

In one embodiment, voltage sensor 215 is coupled to power multiplexer 205 to monitor the voltage on each power line 250. In one embodiment, voltage sensor 215 is coupled via signal lines 260B to solar cells strings 110 to monitor voltage drops across solar cell strings 110, or portions thereof. Voltage measurements may be thresholded and auto shutdown or current path rerouting executed by controller 245 as needed. High voltage readings may be indicative of an open circuit or failed solar cell 115 due to a mechanical or fatigue failure while low voltage readings may be indicative of a short circuit.

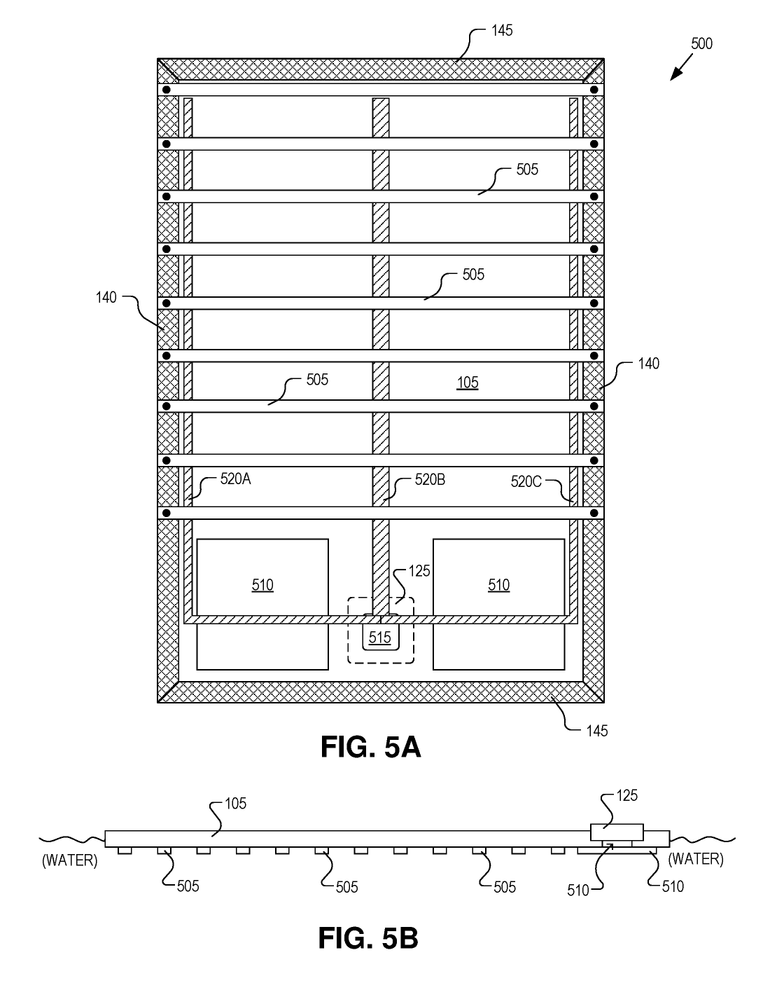

In one embodiment, impedance sensor 220 is coupled to various internal connection points both within laminated support structure 105 and junction box 200 to monitor for insulation failure (e.g., short circuit or low resistance faults to the water), or other fault conditions. For example, in one embodiment, external surfaces (e.g., backside, frontside, etc.) of laminated support structure 105 may be lined with one or more electrodes that are placed in intimate electrical contact with the surrounding environment (discussed in greater detail in connection with FIG. 5A). Since laminated support structure 105 is an insulating laminate that entirely encase solar cells strings 110 and power lines 130 or 250, a low resistance measurement between any of these internal structures and one or more of the external electrodes may be considered indicative of an environmental intrusion. In response, in one embodiment, controller 245 is programmed to issue an alarm via communication interface 235, discharge/shut down, or otherwise place PV macro-module 100 in a safe state, and light one of status indicators 240 to indicate the error condition. Impedance sensors 220 are particularly useful in aqueous environments, such as a floating implementation of PV macro-module 100. In floating embodiments, the external electrode is used to sense ground faults to the water or other insulation fault conditions, which may arise from structural failures that allow water infiltration.

In one embodiment, temperature sensor 225 is integrated into junction box 250 to monitor for an overheat condition and otherwise monitor operating temperatures. Multiple temperature sensors 225 may also be included within distributed circuitry 120 within laminated support structure 105. These temperature sensors may be used to monitor operating temperatures of solar cells 115 themselves, which correlates to operational efficiency and expected lifespan.

Shorting switches 230 are power switches coupled across power lines 250 at various locations to clamp the lines and electrically short or otherwise discharge the system. In one embodiment, shorting switches 230 are integrated into power multiplexer 205 and are coupled across the high and low voltage rails of power lines 250. These shorting switches 230 may be closed circuited in response to a shutdown signal from controller 245 or even coupled to automatically close circuit if any of current monitor 210, voltage sensor 215, impedance sensor 220, or temperature sensor 225 register a relevant fault condition. In some embodiments, shorting switches 230 may be implemented as “normally on” switches that default to a safe state that discharges solar cells 115 when operational control/power is lost. Temperature readings may simply be used to generate operational data logs by controller 245, to trigger safety shutdown protocols, reroute current around solar cells 115 that are deemed to be faulty, or engage active cooling mechanisms when necessary to keep junction box 250 within safe operational temperatures.

FIG. 2B illustrates a demonstrative representation of distributed circuitry 201 embedded throughout a PV macro-module, in accordance with an embodiment of the disclosure. Distributed circuitry 201 is one possible implementation of each instance of distributed circuitry 120 illustrated in FIG. 1. The illustrated embodiment of distributed circuitry 201 includes addressing circuitry 270, a power switch 275, and a bypass diode 280. Distributed circuitry 201 is disposed within laminated support structure 105 and instances distributed throughout PV macro-module 100. In the illustrated embodiment, power switch 275 and bypass diode 280 are coupled in a shunting path across a group of solar cells 115. For example, power lines 281 and 282 are coupled to shunt across a group of solar cells 115. In one embodiment, power lines 281 and 282 may shunt an entire solar cell string 110 or just a portion of a solar cell string 110. Bypass diode 280 provides a bypass path for solar generated current in the event a series connected solar cell 115 fails, is shaded, or becomes an open circuit or high resistance element. Bypass diode 280 is a passive element that is not actively controlled.

In contrast, power switch 275 is an active element controlled by the centralized circuitry within junction box 125. For example, power switch 275 can be activated under the influence of controller 245 in response to the detection of a failure condition or as a user request to shutdown or otherwise discharge PV macro-module 100 for maintenance and/or servicing. Individual instances of power switch 275 are addressed and activated via addressing circuit 270. When a given instance of addressing circuit 270 received a shutdown signal on signal line 271, it closes power switch 275 to thereby clamp and/or discharge the shunted portion of a given solar cell string 110. In various embodiments, instances of distributed circuitry 201 may all share a common signal line 271, may share a multiple signal lines 271, or each have a dedicated signal line. In one embodiment where multiple instances of addressing circuit 270 are coupled to a common signal line 271, the different instances are activated via a different frequency signal. Although FIG. 2B illustrates distributed circuitry 201 as including a single bypass diode 208 and a single power switch 275, it should be appreciated that these elements may be substituted for a network of interconnected diodes and switches that implement the bypass and clamping functions described herein.

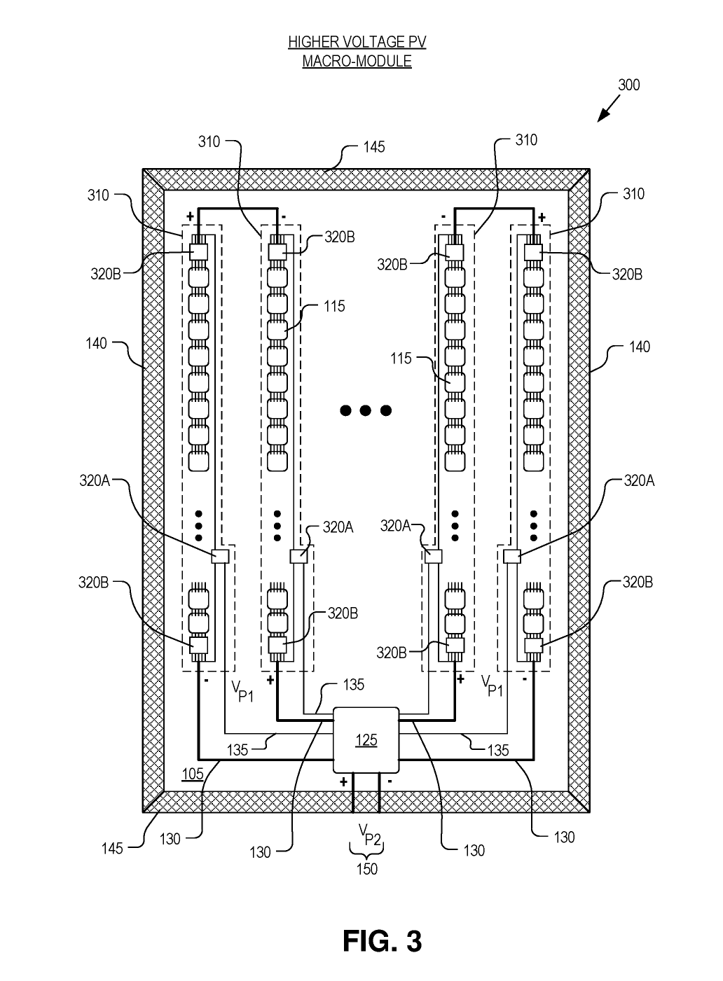

FIG. 3 is an illustration of a higher voltage PV macro-module 300, in accordance with an embodiment of the disclosure. PV macro-module 300 represents a higher voltage implementation of PV macro-module 100 illustrated in FIG. 1. The illustrated embodiment of PV macro-module 300 includes laminated support structure 105, solar cell strings 310 including solar cells 115, distributed circuitry 320A and 320B, junction box 125, power lines 130, signal lines 135, edge connections 140, end connections 145, and output ports 150.

In the illustrated embodiment, each solar cell string 310 includes enough series connected solar cells 115 such that the internal power line voltage V_{P1} is a high voltage value (e.g., 1000V). In one embodiment, the power multiplexer within junction box 125 is coupled to combine the output power from each solar cell string 310 such that the internal power line voltage V_{P1} is equivalent to, or a regulated offset thereof, the output voltage V_{P2} output externally from PV macro-module 300. Accordingly, in the illustrated embodiment, higher voltage PV macro-module 300 includes large numbers of solar cells 115 connected in series between the positive and negative voltage rails of power lines 130 to generate V_{P1}, which is equivalent, or close, to the output voltage V_{P2}. In some embodiments, junction box 125 may include a DC-to-AC inverter, in which case V_{P2} is converted to an AC power signal, or junction box 125 may include a DC-to-DC converter that can step-up (or step down) V_{P2} relative to V_{P1}.

Distributed circuitry 320A may be implemented with embodiments of distributed circuitry 201 illustrated in FIG. 2B. Although FIG. 3 illustrates distributed circuitry 320A as shunting an entire solar cell string 310, which generates half the voltage of V_{P1}, in other embodiments, distributed circuitry 320A may shunt less than a whole solar cell string 310, two solar cell strings 310 coupled in series, or other combinations of series connected solar cells 115. Distributed circuitry 320B is coupled in series with each solar cells string 115. In one embodiment, distributed circuitry 320B represents one or more inline fuses or switches that can be selectively blown/switched under the influence of controller 245 within junction box 125, or in response to a predetermined condition sensed by one or more of current monitor 210, voltage sensor 215, impedance sensor 220, or temperature sensor 225. When the inline fuses are blown, the corresponding series connected branch of a solar cell string 310 is open circuited, such that current must be shunted around the series connected solar cells 115 for operation to continue, or the entire solar cell string 115 is shutdown and taken offline. Although FIG. 3 illustrates each solar cell string 310 as including just a single pair of distributed circuitry 320B, in some embodiments, distributed circuitry 320B (e.g., inline fuses, switches, etc.) may be periodically disposed along a given solar cell string 310 (e.g., every 10 solar cells 115). In this periodic embodiment, distributed circuitry 320B can be open circuited every N (e.g., N=10, 15, etc.) solar cells 115 to place PV macro-module 300 in a safe low voltage state or route current around non-functioning solar cells 115. Distributed circuitry 320A and 320B can be used in conjunction with each other to isolate faulty segments of solar cells 115 from operational segments and route current around the isolated segment.

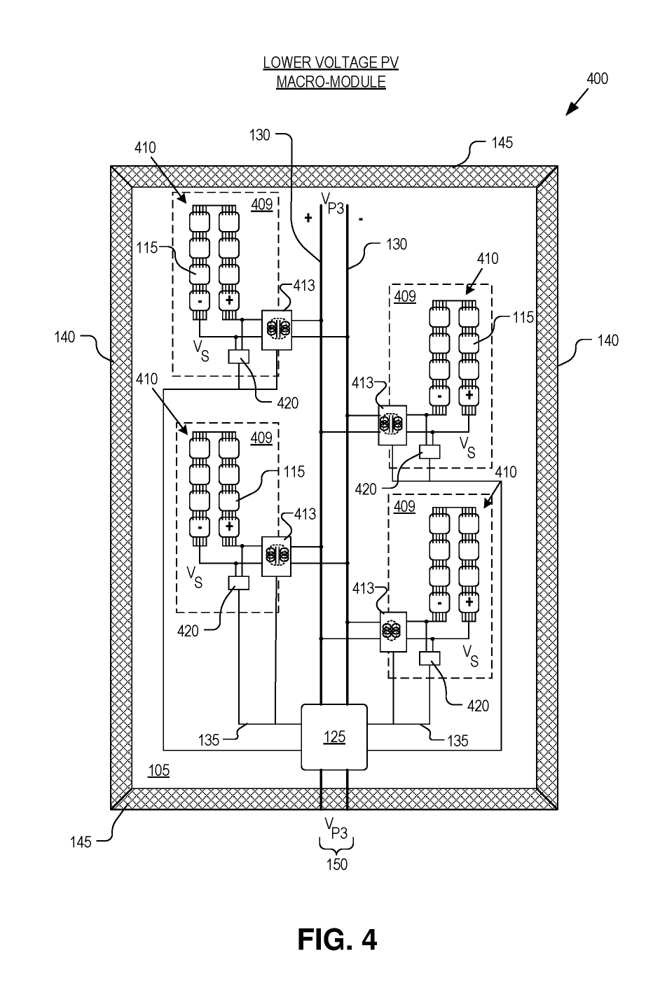

FIG. 4 is an illustration of a lower voltage PV macro-module 400, in accordance with an embodiment of the disclosure. PV macro-module 400 represents a lower voltage implementation of PV macro-module 100 illustrated in FIG. 1. The illustrated embodiment of PV macro-module 400 includes laminated support structure 105, sub-modules 409, converters 413, distributed circuitry 420, junction box 125, power lines 130, signal lines 135, edge connections 140, end connections 145, and output ports 150. The illustrated embodiment of sub-modules 409 include solar cell strings 410 of solar cells 115. In one embodiment, the functionality of distributed circuitry 420 may be incorporated into converters 413. Converters 413 may be implemented as direct current (“DC”)-to-DC converters that steps up a DC voltage or implemented as a DC-to-alternating current (“AC”) inverter that both steps up the absolute value of the voltage and inverts the DC voltage output from solar cells 115 to an AC voltage on power lines 130.

PV macro-module 400 is referred to a lower voltage implementation because each solar cell string 410 includes substantially fewer number of solar cells 115 coupled in series that generate a string voltage Vs that is substantially less than the power line voltage V_{P3}. For example, each solar cell string 410 may include 50 solar cells 115 coupled in series that generate a string voltage Vs of approximately 30 V. Of course other number of series connected solar cells 115 and string voltages Vs that are greater or smaller may be implemented. However, solar cell strings 410 are coupled to power lines 130 via converters 413 that step the string voltage Vs up to the power line voltage V_{P3}. In one embodiment, the power line voltage V_{P3} is 1000V. In some embodiments, converters 413 are implemented using direct electrical connections. In yet other embodiments, converters 413 are implemented using power transformers that couple primary windings on the solar cell string side to secondary windings on the power line side via magnetic flux. This electromagnetic coupling provides a measure of protective isolation between the lower voltage solar cell side and the higher voltage power line side in the event of an environmental breach or electrical short. This means fewer elements within PV macro-module 400 are operating at the higher power line voltage V_{P3}. Those elements operating at the lower string voltage Vs may not need as rigorous protection and insulation as that surrounding elements operating at the higher power line voltage V_{P3}. In one embodiment, components operating at the higher power line voltage V_{P3} (e.g., power lines 130, the secondary windings of converter 413) are not embedded within laminated support structure 105; but rather, are embedded within a separate encapsulation to provide further insulation and isolation between the higher voltage and lower voltage components.

In one embodiment, sub-modules 409 are individually replaceable modules that can be swapped out on an as needed basis. For example, solar cells 115 within a given solar string 410 may be integrated into a separate laminated support structure that mounts onto the base laminated support structure 105. The mounting could be via a hook and loop attachment, a semi-permanent adhesive, snaps, etc. In one embodiment, the break connection point between a given sub-module 409 and power lines 130 is located at the magnetic coupling between the primary and secondary windings of each converter 413. In this way, if a given solar cell string 410 fails or its operational efficiency otherwise drops, just that solar cell string 410 can be replaced by swapping out the failed sub-module 409 for a new sub-module 409. In other replaceable module embodiments, the break connection point may be formed between metallic contacts, or otherwise.

FIG. 5A is a backside illustration of the addition of floating treatments to a PV macro-module 500, in accordance with an embodiment of the disclosure. FIG. 5B is a profile illustration of the same. PV macro-module 500 represents a floating implementation of PV macro-module 100 illustrated in FIG. 1. Furthermore, the internal circuitry of PV macro-module 500 may be implemented as a higher voltage embodiment (FIG. 3) or a lower voltage embodiment (FIG. 4). The illustrated embodiment of the backside (or underside) of PV macro-module 500 includes laminated support structure 105, junction box 125, edge connections 140, end connections 145, floatation pads 505, floatation pads 510, a cutout 515, and external electrode 520 having sections 520A-C.

As mentioned above, PV macro-module 100 is well-suited for deployment over water reservoirs or other water bodies (e.g., pools, ponds, etc.). Deployment over water has benefits beyond the reduction of evaporation from these reservoirs and the fact that many reservoirs do not compete with agriculture demands. In fact, floating PV macro-module 100 over water can provide an effective mechanism for cooling the solar cells and power electronics. Maintaining reduced operating temperatures can increase the inherent efficiency of solar cells 115 while also extending the mean time between failures (“MTBF”) of both solar cells 115 and the centralized electronics within junction box 125.

In the illustrated embodiment, floatation pads 505 are disposed in a pattern beneath solar cell strings 110 to provide buoyancy to solar cell strings 110, distributed circuitry 120, and the bulk of laminated support structure 105. FIG. 5A illustrates floatation pads 505 disposed in a periodic pattern that covers less than 75% of the underside of laminated support structure 105. 75% coverage or less with uniform deployment ensures even floatation support while also allowing direct and substantially uniform exposure of water to the backside of laminated support structure 105 for even cooling. It is anticipated that in alternative embodiments greater than 75% coverage may be feasible as well. Floatation pads 505 can assume a variety of different shapes, cross-sections, and patterns and may be fabricated from a variety of low density materials such as polystyrene foam, hollow high-density polyethylene (“HDPE”), inflatable bladders, etc. In one embodiment, floatation pads 505 are not disposed directly below a solar cell 115, rather, are disposed in peripheral regions or in various patterns that do not place a floatation pad 505 directly below a solar cell 115. This indirect or peripheral placement reduces the concentration of mechanical stresses on solar cells 115 thereby increasing the expected lifespan of solar cells 115.

In the illustrated embodiment, floatation pads 510 are disposed on the backside of laminated support structure adjacent to cutout 515. Floatation pads 510 provide increased buoyancy localized around junction box 125 to carry its additional weight. Floatation pads 510 may be fabricated of the same or different buoyant material as floatation pads 505. Both floatation pads 505 and floatation pads 510 may be fixed to the underside of PV macro-module 500 via mechanical fasteners (e.g., rivets, snaps, etc.), environmentally friendly adhesive, spot melting to form a bond, or otherwise. Junction box 125 is disposed in and/or over cutout 515 to expose at least a portion of a backside of junction box 125 to the water below. Cutout 515 is a hole through laminated support structure 105 that provides good thermal contact between the water and junction box 125 for efficient cooling. Although FIGS. 5A and 5B illustrate cutout 515 as disposed in an interior portion of laminated support structure 105 proximate to one end, in other embodiments, cutout 515 may be disposed directly along an edge or end surface of PV macro-module 500.

In one embodiment, PV macro-module 500 also includes external electrode 520 disposed along the backside of laminated support structure 105. External electrode 520 is externally exposed to provide direct electrical contact with the external environment. In the case of the floating PV macro-module 500, this means external electrode 520 provides electrical contact to the water body over which PV macro-module 500 is floating. As illustrated, electrode 520 is coupled to junction box 125. In one embodiment, impedance sensor 220 is coupled to external electrode 520 to monitor the impedance between external electrode 520 and one or more internal connection points. If a low resistance or short circuit condition is identified, then it can be assumed that laminated support structure 105 has been breached by the water. In other words, external electrode 520 is used to monitor for insulation failure or conduction to the water. To improve the electrical connection between external electrode 520 and the water, the illustrated embodiment of external electrode 520 includes three sections 520A, 520B, and 520C that run along the side edges and up the middle for most, if not all, of the length of PV macro-module 500. Sections 520A and 520C that run along the perimeter edges serve as perimeter safety guard structure. In particular, sections 520A and 520C operate to bend the electric field around the edges of PV macro-module 500 to terminate back on sections 520A and C of external electrode 520. In the event of a failure, this guarding function contains current to the immediate vicinity around the edges of PV macro-module 500 and reduces the likelihood of arcing to structures or people above the waterline.

Other form factors and routing paths for external electrode 520 may be used. External electrode 520 may be fabricated from a variety of conductive materials. In one embodiment, external electrode 520 is a conductive metal tape. In one embodiment, external electrode 520 is riveted through laminated support structure 105 to the frontside using metallic, or otherwise conductive rivets, to provide electrical insulation fault detection or conductivity to the frontside of laminated support structure 105.

FIG. 6A-6D are cross-sectional illustrations of various material stacks for implementing laminated support structure 105, in accordance with embodiments of the disclosure. FIG. 6A illustrates a first material stack 600 for laminated support structure 105 that is compliant/conducive to being rolled for transport or storage of PV macro-module 100. Material stack 600 is also well suited for deployment in an aqueous environment, such as a water reservoir, but may be deployed in a variety of environments both land and water. The illustrated embodiment of material stack 600 includes a substrate layer 605, a water block layer 610, a backside encapsulant layer 615, a frontside encapsulant layer 625, a stiffener layer 630, an ultraviolet (“UV”) blocking layer 635, and a superstrate layer 640.

Frontside encapsulant layer 625 and backside encapsulant layer 615 sandwich around solar cells 110 which are electrically interconnected front to back and back to front by electrodes 620. Both frontside and backside encapsulant layers 625 and 615 conform to and otherwise mold around solar cells 110. In one embodiment, frontside and backside encapsulant layers 625 and 615 are formed of ethylene-vinyl acetate (EVA) each approximately 0.9 mm thick. In other embodiments, frontside and backside encapsulant layers 625 and 615 are fabricated from layers of polyolefin. In one embodiment, heat and pressure are used to encapsulate solar cells 110 between the frontside and backside encapsulant layers. For example, even pressure may be applied using a vacuum tool, which also serves to eliminate deleterious moisture and air pockets.

Substrate layer 605 provides physical environmental protection to the backside of solar cells 110. In particular, substrate layer 605 protects against damage occurring from physical impacts, animal influence, and other forms of physical intrusions from the backside. In one embodiment, substrate 605 is fabricated of polyethylene terephthalate (PET) approximately 0.27 mm thick. In one embodiment, substrate layer 605 is pigmented black in color.

Water block layer 610 is an optional waterproofing layer that can extend the lifespan of solar cells 110 when PV macro-module 100 is deployed as a floating module. Water block layer 610 may be fabricated of a metal foil layer, such as aluminum foil, an oxide layer, such as silicon dioxide, or otherwise.

Stiffener layer 630 is a layer that adds stiffness to PV macro-module 100 to reduce the incidence of fracture of solar cells 110 due to external mechanical disturbances (e.g., wave action, wind, hail, etc.). In addition to the mechanical protection provided, stiffener layer 630 operates to limit the bend radius when PV macro-module 100 is rolled. In the illustrated embodiment, stiffener layer 630 is disposed across the top side of solar cells 110. Stiffener layer 630 may be fabricated of a polymer material having the desired stiffness, such as a 0.27 mm thick layer of clear polyphenyl ether (PPE).

In one embodiment, UV blocking layer 635 is also an adhesive that is disposed between superstrate layer 640 and stiffener layer 630 to bond the two layers together. UV blocking layer 635 includes UV filtering characteristics to block or otherwise reduce the amount of harmful UV light that penetrates to the lower layers. UV light can age or otherwise damage the underlying material layers thereby shortening the deployed lifespan of PV macro-module 100. In one embodiment, UV blocking layer 635 is a 0.2 mm thick layer of UV blocking EVA encapsulant.

Superstrate layer 640 provides physical environmental protection to the frontside of solar cells 110. In particular, superstrate layer 640 protects against damage occurring from physical impacts, animal influence, and other forms of physical intrusions from the frontside. In one embodiment, superstrate layer 640 is fabricated of a polymer material. For example, in one embodiment, superstrate layer 640 is a 0.2 mm thick layer of a fluoropolymer such as ethylene tetrafluoroethylene (ETFE).

FIG. 6B illustrates a second material stack 601 for laminated support structure 105 that is also compliant to being rolled for transport or storage of PV macro-module 100. Material stack 601 is also well suited for deployment in an aqueous environment, such as a water reservoir. Material stack 601 is similar to material stack 600 except for substrate layer 645. Substrate layer 645 provides physical environmental protection to the backside of solar cells 110, but also includes integrated buoyancy. In particular, substrate layer 645 includes low density regions dispersed throughout the layer to provide increased buoyancy over substrate layer 605. Embedding low density regions may be done in place of the buoyancy treatments added to the underside, as illustrated in FIGS. 5A and 5B, or in addition thereto. The low density regions may be air pockets, voids, embedded foam, hollow glass beads, or other low density particles dispersed within substrate layer 645. In one embodiment, air pockets may be intentionally captured during a lamination process of material stack 601 to provide integrated buoyancy.

FIG. 6C illustrates a third material stack 602 for laminated support structure 105 that is also compliant to being rolled for transport or storage of PV macro-module 100. Material stack 602 is also well suited for deployment in an aqueous environment, such as a water reservoir. Material stack 602 is similar to material stack 600 except that stiffener layer 630, UV blocking layer 635, and superstrate layer 640 have been replaced with a single glass panel layer 650. In one embodiment, glass panel layer 650 is adhered directly to frontside encapsulant layer 625 using heat and pressure (e.g., application of a vacuum). Glass panel layer 650 is typically less than 3.2 mm thick and in rollable embodiments is expected to be less than 500 um thick.

FIG. 6D illustrates a fourth material stack 603 for laminated support structure 105 that is also compliant to being rolled for transport or storage of PV macro-module 100. Material stack 603 is also well suited for deployment in an aqueous environment, such as a water reservoir. Material stack 603 is similar to material stack 602 except that substrate layer 605 and water block layer 610 have been replaced with a single glass panel layer 651. In other words, backside glass panel layer 651 serves as both the substrate layer to provide physical environmental protection and the water block layer to block water from penetrating to the in-panel electronics. In one embodiment, both frontside glass panel layer 650 and backside glass panel layer 651 adhere directly to frontside encapsulant layer 625 and backside encapsulant layer 615, respectively, using heat and pressure (e.g., application of a vacuum). In the illustrated embodiment, the edges of material stack 603 are hermetically sealed with glass frits 660. Other edge sealing techniques may be implemented. In one rollable embodiment, both glass panel layers 650 and 651 are approximately 400 um thick. In other embodiments, glass panel layers 650 and 651 may range between 50 um and 3.2 mm, though thickness substantially above 500 um may be more useable for foldable implementations as opposed to rollable implementations.

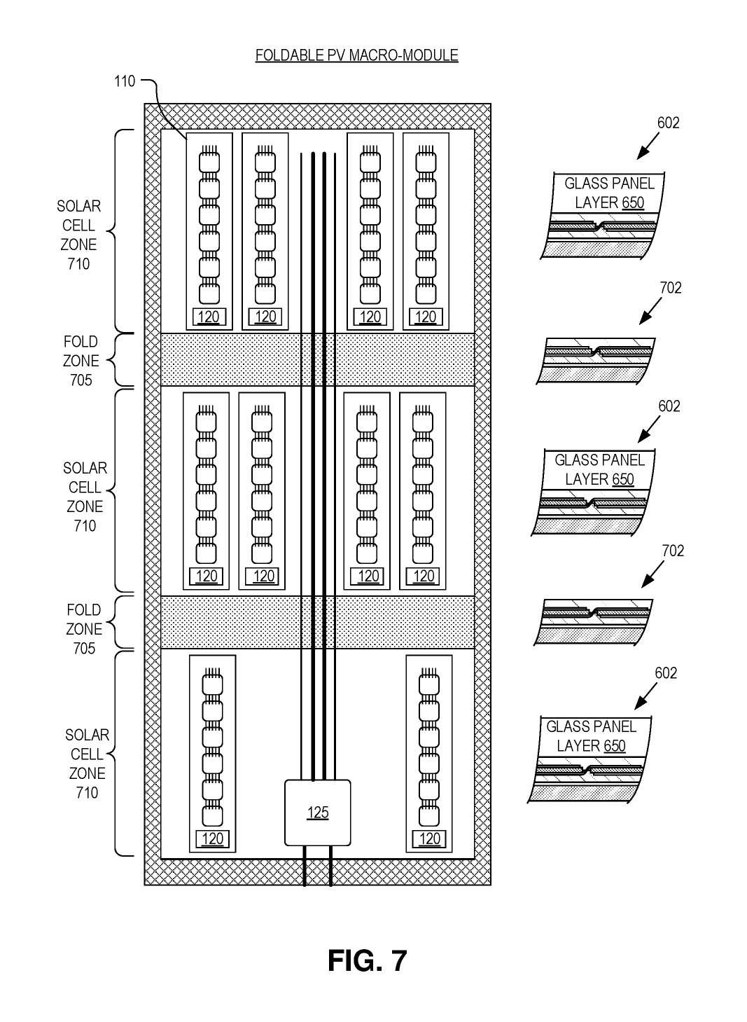

FIG. 7 is an illustration of a foldable PV macro-module 700 including fold zones and solar cell zones, in accordance with an embodiment of the disclosure. PV macro-module 700 is one possible implementation of PV macro-module 100 illustrated in FIG. 1 and may be implemented as a higher voltage embodiment (FIG. 3) or a lower voltage embodiment (FIG. 4). The illustrated embodiment of PV macro-module 700 includes fold zones 705 and solar cell zones 710 formed on a laminated support structure having non-uniform stiffness. In particular, fold zones 705 have a reduced rigidity or reduced stiffness compared to solar cell zones 710. Fold zones 705 operate as localized folding locations so that PV macro-module 700 can be folded in sections for storage or transportation. Solar cell zones 710 include the solar cell strings 110 and distributed circuitry 120 with one of the solar cell zones 710 also including junction box 125. Solar cell zones 710 have reduced flexibility and increased stiffness to protect the in-panel electronics.

FIG. 7 further illustrates example material stacks 602 and 702, which correspond to solar cell zones 710 and fold zones 705, respectively. As seen in the depicted embodiment, material stacks 602 include glass panel layer 650 which extends over just solar cell zones 710; however, material stacks 702 do not include an overlaying glass panel layer. By including a glass panel layer 650 disposed over the frontside encapsulant layer in solar cell zones 710, the in-panel electronics are protected. By not extending the glass panel layer 650 over fold zones 705 which merely include electrical connections that extend through, fold zones 705 have greater flexibility. Since fold zones 705 do not include solar cells, less environmental protection is needed and it is not necessary to limit the bend radius to the same degree as for solar cell zones 710. Material stacks 602 and 702 are merely demonstrative examples; however, fold zones 705 can be fabricated of other material layer stacks that are more flexible and/or provide less environmental protection than is used with solar cell zones 710.

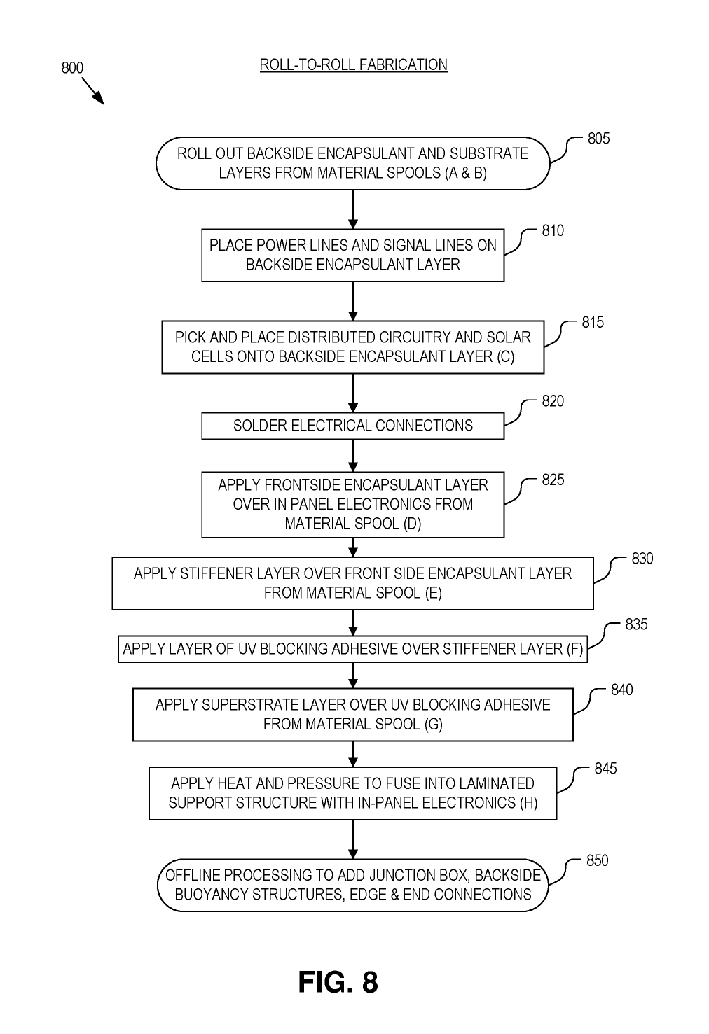

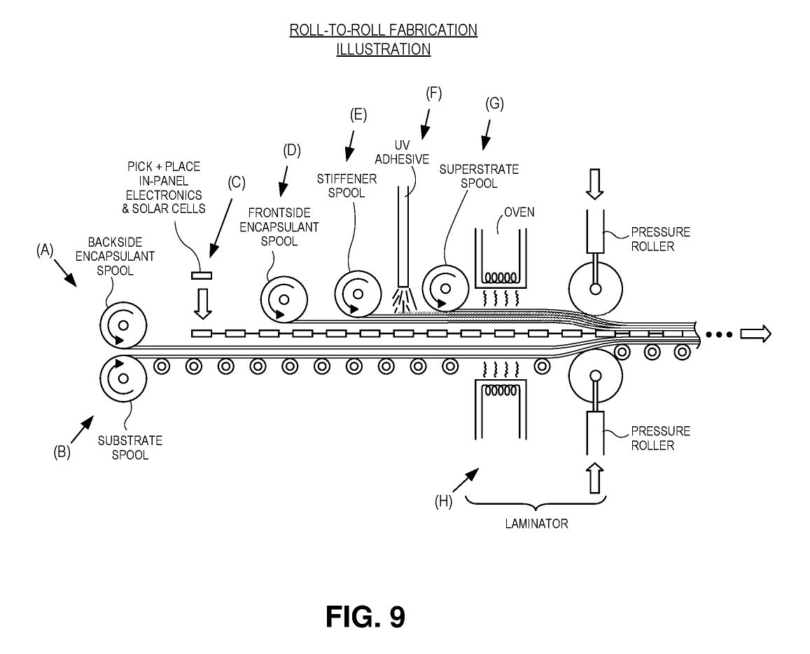

FIG. 8 is a flow chart illustrating a process 800 of roll-to-roll fabrication of PV macro-module 100, in accordance with an embodiment of the disclosure. Process 800 is described with reference to FIG. 9, which illustrates the roll-to-roll fabrication technique, in accordance with an embodiment of the disclosure. The order in which some or all of the process blocks appear in process 800 should not be deemed limiting. Rather, one of ordinary skill in the art having the benefit of the present disclosure will understand that some of the process blocks may be executed in a variety of orders not illustrated, or even in parallel.

In a process block 805, the backside encapsulant layer (e.g., layer 615) and the substrate layer (e.g., layer 605) are unrolled from their respective material spools (see A & B in FIG. 9). In an embodiment that includes a water block layer (e.g., layer 610) disposed between the backside encapsulating layer and the substrate layer, the water block layer is also unrolled (not illustrated). In one embodiment, all three layers may come pre-rolled on a single material spool and thus collectively unrolled together. A length of these material layers is unrolled and extended along the fabrication line. It is noteworthy that process 800 describes a continuous roll-to-roll process where PV macro-modules are fabricated from lengths of material layers as they are continuously unrolled from their respective material spools.

In process blocks 810 to 820 the in-panel electronics (including solar cells and conductive lines) are picked and placed and connected (see C in FIG. 9). For example, in a process block 810, the power lines 130 and signal lines 135 are placed onto an unrolled section of the backside encapsulant layer. Additional layers to electrically insulate signal lines may be used. In process block 815, solar cells 115 and distributed circuitry 120 are picked and placed into location. With the individual components and conductive lines laid up, the electrical connections between the in-panel electronics, solar cells, and conductive lines are soldered (process block 825). In some embodiments, distributed circuitry 120 and various electrical connections may be placed behind solar cells 115 to increase packing densities/fill factors of solar cells 115. It should be appreciated that the order of process blocks 810, 815, and 820 may be altered. For examples, electronics may be placed before power lines 130 and/or signal lines 135 are routed in position. Similarly, sub-modules of the electronics may be soldered together before the pre-assembled sub-module is placed into position. Furthermore, the pick and placement of the in-panel electronics and the soldering of the interconnections may occur contemporaneously with the unrolling of the material spools and as the material layers are moving down the fabrication line, or intermittently in a stop-and-go manner. The intermittent embodiments may be referred to as a step and repeat roll-to-roll process. During step and repeat, the material spools are unrolled and advanced into position, then paused for a duration. After a requisite time for processing the material layers are indexed forward and the material spools unrolled. For example, processing may be paused at a pick and place station for layup, placement of in-panel electronics, and soldering connections, and/or at the laminator station for the application of heat and pressure.

In a process block 825, the frontside encapsulant layer (e.g., layer 625) is applied from its material spool and laid over the in-panel electronics (see D in FIG. 9). Subsequently, in a process block 830, the stiffener layer (e.g., layer 630) is applied over the frontside encapsulant layer (see E in FIG. 9) from its material spool. The remaining layers are built up in turn with the additional of a UV blocking layer (process block 835; see F in FIG. 9) and the application of the superstrate layer (e.g., layer 640) from its material spool over the UV blocking layer (process block 840; see G in FIG. 9). Although FIG. 9 illustrates the UV blocking layer as being a spray on application, in other embodiments, the UV blocking layer is a film that is also applied from a material spool in a similar manner to the other material layers.

FIGS. 8 and 9 illustrate a bottom up approach to building the multi-layer sandwich that forms laminated support structure 105. However, it is also possible to implement the roll-to-roll fabrication technique using a top down approach. In a top down approach, the superstrate layer, the UV blocking layer, the stiffener layer, and the frontside encapsulant layer are unrolled first and the in-panel electronics are disposed upside down onto sections of the unrolled frontside encapsulant layer. The backside layers including the backside encapsulant layer, the water blocking layer, and the substrate layer would then be overlaid. In either case, the in-panel electronics (e.g., solar cells, distributed circuitry, power lines, signal lines, etc.) are sandwiched directly between the frontside and backside encapsulant layers.

Returning to FIG. 8, in a process block 845, the sandwich stack of material layers and in-panel electronics (including solar cells) are laminated using heat and pressure (see H in FIG. 9). For example, pressure may be applied via application of a vacuum, rollers, inflatable bladders, a press, etc. The pressure also serves to eliminate deleterious moisture and air pockets. The lamination process causes the frontside and backside encapsulant layers to mold around and otherwise intimately conform to the solar cells 115 and distributed circuitry 120. This serves to protectively encase the electronics.

After lamination, the laminated support structure 105 rolls off the fabrication line as a mat-like structure that is compliant to folding. The remaining components are added or machined into the laminated support structure 105 as offline processing (process block 850). For example, a hole is cut into laminated support structure 105 to mount junction box 125 and form electrical connections to power lines 130 and signal lines 135 disposed therein. In some embodiments, the hole may be precut into the laminated support structure layers prior to lamination. Buoyancy structures, such as those illustrated in FIGS. 5A and 5B, may be attached for various floating solar embodiments. The edge connections 140 (e.g., zipper connections) and end connections 145 (e.g., grommets) may also be attached/installed offline.

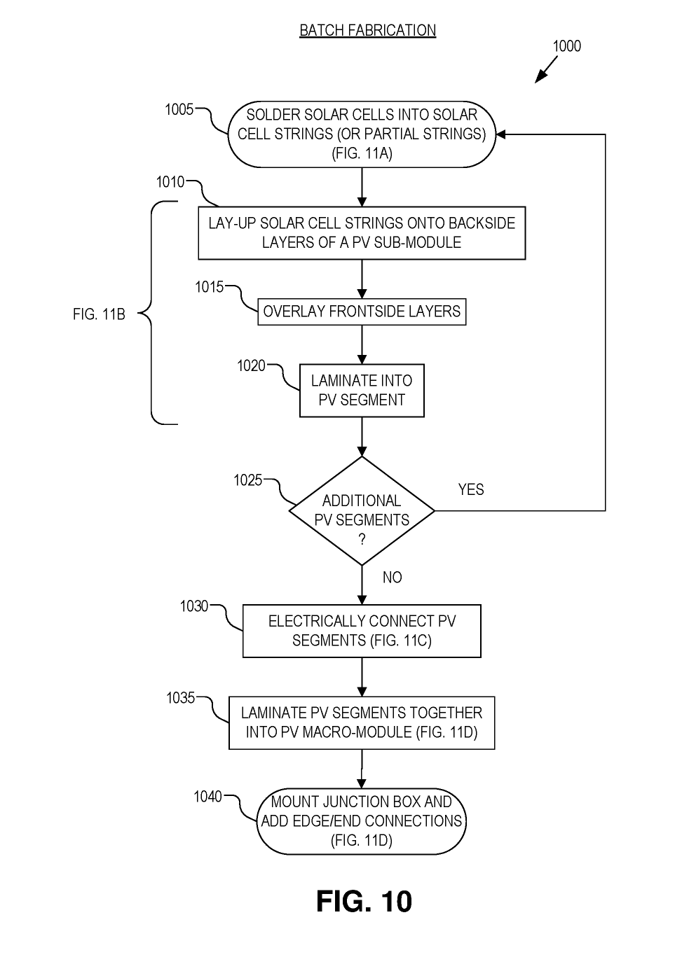

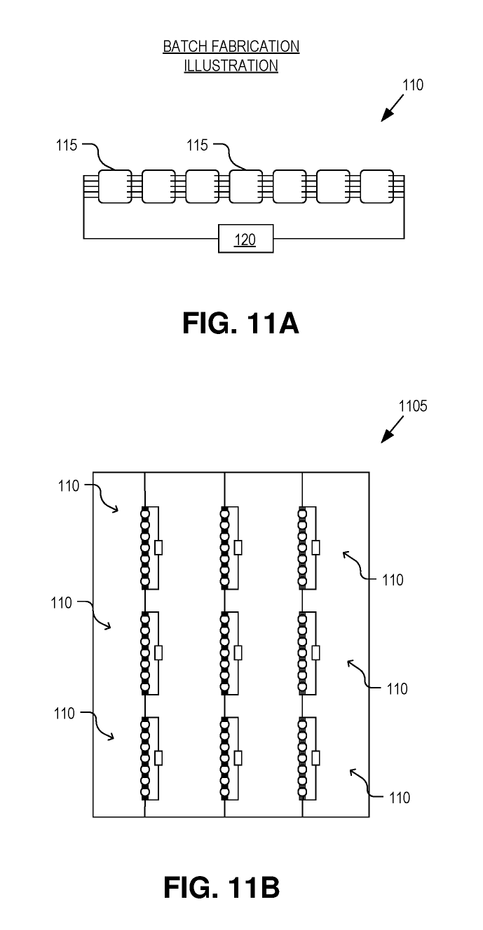

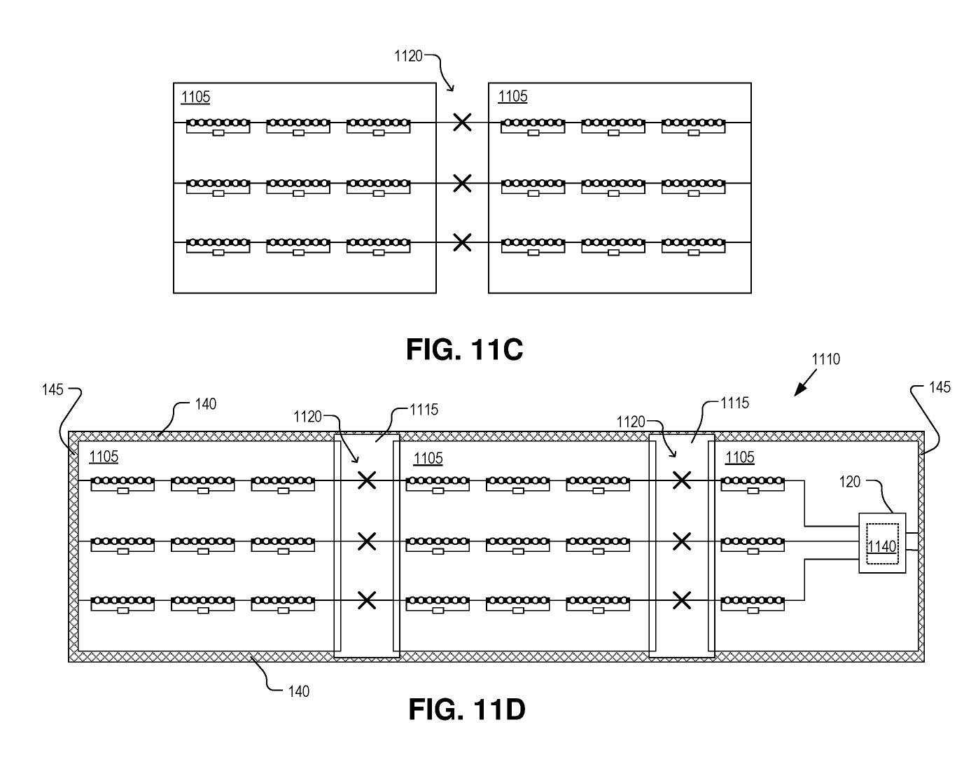

FIG. 10 is a flow chart illustrating a process 1000 of batch fabrication of PV macro-module 100, in accordance with an embodiment of the disclosure. Process 1000 is described with reference to FIGS. 11A-11D, which illustrates different fabrication sub-steps. The order in which some or all of the process blocks appear in process 1000 should not be deemed limiting. Rather, one of ordinary skill in the art having the benefit of the present disclosure will understand that some of the process blocks may be executed in a variety of orders not illustrated, or even in parallel.

In a process block 1005, solar cells 115 and distributed circuitry 120 are soldered into solar cell strings 110 or partial solar cell strings (FIG. 11A). In one embodiment, a batch of solar cell strings 110 are pre-assembled and soldered. In a process block 110, the pre-assembled solar cell strings 110 are laid face up on the backside layers including, for example, substrate layer 605, water block layer 610, and backside encapsulant layer 615. Alternatively, batches of the solar cell strings 110 may be placed face down on the frontside side layers (not illustrated). The opposing layers of the material stack are then overlaid, which as illustrated in process 1000 includes overlaying the frontside layers (e.g., frontside encapsulant layer 625, stiffener layer 630, UV blocking layer 635, and superstrate layer 640). Finally, in a process block 1020, the material stack sandwich of backside layers and frontside layers with the in-panel electronics disposed there between are laminated together using heat and pressure to form a PV segment 1105 (see FIG. 11B). A vacuum may be used to apply pressure and to prevent deleterious air and moisture from being trapped in the laminate. Each PV segment 1105 represent a portion or segment of laminated support structure 105 with the in-panel electronics (e.g., solar cell strings 110, distributed circuitry 120, power lines 130, and signal lines 135) embedded therein. Process 1000 may loop back and repeat process 1005 through 1025 until a specified number of PV segments 1105 have been fabricated (decision block 1025).

Once at least the requisite number of PV segments 1105 have been fabricated to fully populate an entire PV macro-module 100, then process 1000 continues to a process block 1030. A single PV macro-module 100 may include 10's, 100's, or even thousands of PV segments 1105.

In a process block 1030, the individual PV segments 1105 are electrically connected together (see FIG. 11C). In one embodiment, electrically connecting PV segments 1105 includes soldering power lines 130 and signal lines 135 together. Other forms of electrical connections may be used.

In a process block 1035, the electrically connected PV segments 1105 are laminated together to form a cohesive or single contiguous module 1110 (see FIG. 11D). In one embodiment, laminating PV segments 1105 together includes the use of lamination sections 1115 that seal and protect the inter-segment electrical connections 1120 and bind the PV segments 1105 together into the single contiguous module 1110. Lamination sections 1115 may include the same or similar material layers included within the material stack of PV segments 1105. In one embodiment, PV segments 1105 correspond to solar cell zones 710 and lamination sections 1115 correspond to fold zones 705 (see FIG. 7).

Finally, in a process block 1040, a hole 1125 is cut into one of the PV segments 1105 onto which junction box 125 is mounted. In some embodiments, a first portion of the junction box structure is laminated into laminated support structure 105 to provide electrical connections while a second portion is mounted and sealed/closed over the first portion. In one embodiment, end connections 145 and edge connections 140 may also be added. Upon completion, the single contiguous module 1110 represents one possible fabricated implementation of PV macro-module 100, in accordance with an embodiment of the disclosure.

The above description of illustrated embodiments of the invention, including what is described in the Abstract, is not intended to be exhaustive or to limit the invention to the precise forms disclosed. While specific embodiments of, and examples for, the invention are described herein for illustrative purposes, various modifications are possible within the scope of the invention, as those skilled in the relevant art will recognize.

These modifications can be made to the invention in light of the above detailed description. The terms used in the following claims should not be construed to limit the invention to the specific embodiments disclosed in the specification. Rather, the scope of the invention is to be determined entirely by the following claims, which are to be construed in accordance with established doctrines of claim interpretation.

What is claimed is:

1. A photovoltaic (“PV”) macro-module for solar power generation, the PV macro-module comprising:
a plurality of solar cell strings to generate solar power in response to light incident upon a frontside of the solar cell strings, wherein each of the solar cell strings includes a plurality of solar cells electrically connected in series; and
a laminated support structure in which the solar cell strings are encased, wherein the laminated support structure is compliant to rolling or folding, the laminated support structure including:
a substrate layer to provide physical environmental protection to a back side of the solar cell strings;
a backside encapsulant layer disposed between the substrate layer and the solar cell strings, the backside encapsulant layer conforming to and molding around the back side of the solar cell strings; and
a frontside encapsulant layer conforming to and molding around the frontside of the solar cell strings.

2. The PV macro-module of claim 1, wherein the laminated support structure further comprises:
a stiffener layer disposed across the frontside encapsulant layer, wherein the stiffener layer comprises a first polymer material that adds stiffness to reduce incidence of damage to the solar cells when the PV macro-module is subject to mechanical stress;
a superstrate layer disposed over the stiffener layer to provide physical environmental protection to the frontside of the solar cell strings, wherein the superstrate layer comprises a second polymer material; and
an ultraviolet blocking layer disposed between the superstrate layer and the stiffener layer.

3. The PV macro-module of claim 2, wherein the laminated support structure further comprises a water block layer disposed between the substrate layer and the backside encapsulant layer.

4. The PV macro-module of claim 3, wherein the water block layer comprises a metal foil layer.

5. The PV macro-module of claim 1, wherein substrate layer includes low density regions dispersed throughout to provide buoyancy to the PV macro-module.

6. The PV macro-module of claim 1, further comprising:
distributed circuitry disposed in the laminated support structure and coupled to the solar cell strings to selectively route current generated by the solar cells within the solar cell strings; and
a junction box disposed within a cutout of the laminated support structure, wherein the junction box includes a power multiplexer and a controller coupled to the distributed circuitry, the controller including logic to control the selective routing of the current generated by the solar cells, wherein the cutout exposes a back side of the junction box directly to water for cooling when the PV macro-module is floating on the water.

7. The PV macro-module of claim 6, further comprising:
first floatation pads disposed in pattern along an underside of the laminated support structure beneath the solar cell strings to provide buoyancy to the solar cell strings and distributed circuitry, wherein the pattern has a coverage of less than 75% on the underside; and
second floatation pads disposed on the underside of the laminated support structure adjacent to the cutout to provide buoyancy to the junction box.

8. The PV macro-module of claim 6, wherein the distributed circuitry comprises:
power switches disposed within the laminated support structure and distributed throughout the PV macro-module, where each of the power switches is coupled in a shunting path across a different group of the solar cells; and
addressing circuits each coupled to one of the power switches and disposed within the laminated support structure, wherein each of the addressing circuits is further coupled to the controller to selectively short circuit the shunting path in response to a shutdown signal received from the controller.

9. The PV macro-module of claim 6, further comprising:
an external electrode disposed on a bottom side of the PV macro-module and exposed to water when the PV macro-module is floating on the water; and
an impedance sensor disposed within junction box and coupled to the external electrode and coupled to one or more internal connection points within the laminated support structure, wherein the controller is coupled to monitor the impedance sensor to determine whether a conduction fault condition exists between the one or more internal connection points within the laminated support structure and the water.

10. The PV macro-module of claim 1, further comprising:
edge connections that extend along side edges of the PV macro-module for mechanically connecting the PV macro-module to other PV macro-modules; and
end connections that extend along end edges of the PV macro-module for mechanically holding the PV macro-module taut when unfolded or unrolled over water, wherein the sides edges are longer than the end edges.

11. The PV macro-module of claim 1, wherein the laminated support structure includes fold zones disposed between solar cell zones that include the solar cells, wherein the fold zones have a reduced rigidity compared to the solar cell zones for folding the PV macro-module.

12. The PV macro-module of claim 11, wherein the laminated support structure comprises:
glass panels disposed over the frontside encapsulant layer in the solar cell zones, wherein the glass panels do not extend over the fold zones.

13. The PV macro-module of claim 1, wherein the substrate layer comprises a backside glass panel layer, the PV macro-module of claim 1 further comprising:
a frontside glass panel layer disposed across the frontside encapsulant layer,
wherein the frontside and backside glass panel layers are each less than 500 um thick and compliant to rolling.

14. A photovoltaic (“PV”) macro-module for solar power generation, the PV macro-module comprising:
a laminated support structure that is compliant to either folding or rolling of the PV macro-module;
a plurality of solar cell strings disposed in or on the laminated support structure, wherein each of the solar cell strings includes a plurality of solar cells electrically connected in series to generate solar power in response to light incident upon a frontside of the solar cell strings;
distributed circuitry disposed in or on the laminated support structure and coupled to the solar cell strings to selectively route current generated by the solar cells within the solar cell strings;
a power multiplexer mounted to the laminated support structure, the power multiplexer coupled to combine the solar power received from the solar cell strings for output from the PV macro-module; and
a controller coupled to the distributed circuitry, the controller including logic to control the selective routing of the current generated by the solar cells.

15. The PV macro-module of claim 14, wherein the distributed circuitry includes:
a pair of inline fuses or switches surrounding a group of the solar cells, wherein the pair of inline fuses or switches are coupled to be selectively open circuited in response to the controller; and
a shunting switch coupled to selectively route the current around the group of the solar cells, wherein the shunting switch is coupled to the controller to selectively route the current in response to a signal from the controller.

16. The PV macro-module of claim 14, wherein the power multiplexer and the controller are integrated into a junction box, wherein a cutout of the laminated support structure is disposed at one end of the laminated support structure and the junction box is disposed within the cutout and forms electrical connections to power lines and signal lines disposed within the laminated support structure that extend to the solar cells strings and the distributed circuitry, respectively.

17. The PV macro-module of claim 14, further comprising:
edge connections that extend along side edges of the PV macro-module for mechanically connecting the PV macro-module to other PV macro-modules; and
end connections that extend along end edges of the PV macro-module for mechanically holding the PV macro-module in place when unfolded or unrolled, wherein the sides edges are longer than the end edges.

18. The PV macro-module of claim 14, further comprising:
power lines coupled to the power multiplexer and extending within the laminated support structure; and
converters each coupled between the power lines and a corresponding one of the solar cell strings to step up string voltages received from the solar cell strings to a power line voltage for delivery to the power multiplexer, wherein the power line voltage is greater than the string voltages.

19. The PV macro-module of claim 18, wherein the solar cell strings are disposed within individually replaceable modules and wherein break connection points between the individually replaceable modules and the power lines are formed at magnetic couplings between primary and secondary windings of transformers within the converters.

20. The PV macro-module of claim 14, wherein the distributed circuitry comprises:
power switches disposed within the laminated support structure and distributed throughout the PV macro-module, where each of the power switches is coupled in a shunting path across a different group of the solar cells; and
addressing circuits each coupled to one of the power switches and disposed within the laminated support structure, wherein each of the addressing circuits is further coupled to the controller to selectively short circuit the shunting path in response to a shutdown signal received from the controller.

21. The PV macro-module of claim 20, wherein at least a plurality of the addressing circuits are coupled to the controller via a common signal line and wherein the addressing circuits coupled via the common signal line each monitor a different frequency signal for activation.

22. The PV macro-module of claim 21, wherein the distributed circuitry further comprises:
inline fuses disposed within the laminated support structure and each coupled inline with one of the solar cell strings, wherein the inline fuses are coupled to be selectively blown in response to a signal from the controller to isolate a corresponding one of the solar cell strings from others of the solar cell strings.

23. The PV macro-module of claim 14, further comprising:
an external electrode disposed on a bottom side of the PV macro-module and exposed to an environment surrounding the PV macro-module; and
an impedance sensor coupled to the external electrode and coupled to one or more internal connection points within the laminated support structure, wherein the controller is coupled to monitor the impedance sensor to determine whether a conduction fault condition exists between the one or more internal connection points within the laminated support structure and the environment.

24. The PV macro-module of claim 23, wherein the external electrode includes at least two sections that each extend adjacent to a respective side edge of the PV macro-module.

25. The PV macro-module of claim 14, wherein the laminated support structure includes fold zones disposed between solar cell zones that include the solar cells, wherein the fold zones have a reduced rigidity compared to the solar cell zones for folding the PV macro-module.

26. The PV macro-module of claim 25, wherein the laminated support structure comprises:
a substrate;
frontside and backside encapsulant layers that conform to and mold around the solar cell strings, wherein the backside encapsulant layer is disposed across the substrate; and
glass panels disposed over the frontside encapsulant layer in the solar cell zones, wherein the glass panels do not extend over the fold zones.
